(19) United States
(12) Patent Application Publication
(10) Pub. No.: US 2025/0285987 A1
(43) Pub. Date: Sep. 11, 2025

(54) ON-THE-FLY ANGULAR ALIGNMENT FOR WRITING 3D FEATURES IN A MOUNTED SUBSTRATE

(71) Applicant: Intel Corporation, Santa Clara, CA (US)

(72) Inventors: Khaled Ahmed, San Jose, CA (US); Nicholas Psaila, Pheonix, AZ (US); Benjamin Duong, Lanark (GB)

(73) Assignee: Intel Corporation, Santa Clara, CA (US)

(21) Appl. No.: 18/597,585

(22) Filed: Mar. 6, 2024

(51) Int. Cl. H01L 23/544; G02B 6/42; H01L 21/48; H01L 21/66; H01L 23/00; H01L 23/15; H01L 23/498

(52) U.S. Cl. CPC H01L 23/544; G02B 6/4214; H01L 21/4803; H01L 22/20; H01L 23/15; H01L 23/49827; H01L 24/16; H01L 2223/54426; H01L 2224/16227

(57) ABSTRACT

Apparatuses, systems, and techniques related to angular alignment of a substrate for writing 3D features are described. Angled incident light is emitted onto an angular alignment grating on or within a surface of a substrate workpiece. Reflected light is received from the angular alignment grating and an angle of at least a portion of the surface in the local vicinity of the angular alignment grating is determined based on the received reflected light. A voxel location within the substrate workpiece is adjusted based on the surface angle of the substrate workpiece.

### BACKGROUND

Higher performance, lower cost, increased miniaturization, greater packaging density, and increased product flexibility of integrated circuit devices are ongoing goals of the electronics industry. As the demand for more powerful computing increases and the semiconductor industry moves into the heterogeneous era that uses multiple chiplets in a package, improvements in signaling speed, power delivery, design rules, and stability of package substrates are essential.

Glass substrates possess superior mechanical, physical, and optical properties that allow more transistors to be connected in a package, providing better scaling, and enabling assembly of larger chiplet complexes (e.g., “system-in-package” products) compared to current organic substrates. Chip architectures will have the ability to pack more tiles (also called chiplets) in a smaller footprint on one package, while achieving performance and density gains with greater flexibility and lower overall cost and power usage. Specifically, glass substrates can tolerate higher temperatures, offer about 50% less pattern distortion, have ultra-low flatness for improved depth of focus for lithography, have the dimensional stability needed for extremely tight layer-to-layer interconnect overlay, and allow for optical signaling via glass waveguides. As a result of these distinctive properties, a 10× increase in interconnect density is possible on glass substrates. Furthermore, improved mechanical properties of glass enable ultra-large form-factor packages with very high assembly yields.

However, processing improvements are needed for fabricating devices that utilize glass substrates. It is with respect to these and other considerations that the present improvements have been needed. Such improvements may become critical as the desire to deploy advanced heterogenous systems in integrated circuit device products becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a cross-sectional side view of an integrated circuit system having one or more angular alignment features on a glass substrate;

FIG. 1B illustrates a top-down cross-sectional view of a glass substrate component including angular alignment features and optical features such as waveguides formed within the glass substrate;

FIG. 2 illustrates a side view of angled optical probing of a substrate workpiece including angular alignment features;

FIG. 3 illustrates a top-down view of an example substrate workpiece including angular alignment features within a central region and a perimeter region of the substrate workpiece;

FIG. 4 illustrates a top-down view of an example substrate workpiece including angular alignment features only within a perimeter region of the substrate workpiece;

FIG. 5 illustrates a top-down view of an example integrated circuit system including angular alignment features at each corner of a glass substrate;

FIG. 6 illustrates a top-down view of an example integrated circuit system including angular alignment features along each edge of a glass substrate;

FIG. 7 illustrates a side view of retro-reflected angled optical probing of a substrate workpiece;

FIG. 8 illustrates a top-down view of an example linear array layout of angular alignment features;

FIG. 9 illustrates a top-down view of an example serpentine array layout of angular alignment features;

FIG. 10 illustrates a side view of retro-reflected angled optical probing of a substrate workpiece having angular alignment features that are formed within a top surface of the substrate workpiece;

FIG. 11 illustrates a side view of retro-reflected angled optical probing of a substrate workpiece having angular alignment features with angular surfaces that are formed within a top surface of the substrate workpiece;

FIG. 12 is a flow diagram illustrating methods for forming angular alignment features and using the angular alignment features to align a glass substrate for 3D laser scribing;

FIG. 13 is a diagram of an example system using angular alignment features to map surface angles of a glass substrate;

FIG. 14 is a diagram of an example system for using adjustments based on the angular alignment features to align and 3D laser scribe a glass substrate;

FIG. 15 is a diagram of exemplary on-the-fly 3D laser scribing adjustments based on angular alignment features;

FIG. 16 illustrates an example 3D optical waveguide including a glass substrate with angular alignment features;

FIG. 17 illustrates an example microelectronic device assembly including a glass substrate with an angular alignment feature;

FIG. 18 illustrates exemplary systems deploying a glass substrate with angular alignment feature; and

FIG. 19 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 99% of the particular material or component. Unless otherwise indicated, such material percentages are based on atomic percentage. As used herein, the terms “monolithic”, “monolithically integrated”, and similar terms indicate the components of the monolithic overall structure form an indivisible whole not reasonably capable of being separated.

The term “package” generally refers to a self-contained carrier of one or more dies, where the dies are attached to the package substrate, and may be encapsulated for protection, with integrated or wire-boned interconnects between the dies and leads, pins or bumps located on the external portions of the package substrate. The package may contain a single die, or multiple dies, providing a specific function. The package is usually mounted on a printed circuit board for interconnection with other packaged integrated circuits and discrete components, forming a larger circuit. Here, the term “dielectric” and the term “insulative and any similar term generally refers to any number of non-electrically conductive materials that make up the structure of a package substrate. For purposes of this disclosure, dielectric material may be incorporated into an integrated circuit package as layers of laminate film or as a resin molded over integrated circuit dies mounted on the substrate. Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric. Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together. Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

Apparatuses, systems, and techniques are described herein related to on-the-fly angular alignment for writing 3D features in a mounted substrate. For example, the discussed techniques, alignment features, and systems improve the accuracy of laser inscribing features into a mounted glass substrate.

As discussed, glass substrates possess a variety of advantages relative to other substrate materials such as organic substrates. However, difficulties persist in fabricating devices using glass substrates. For example, ultrashort pulse laser writing offers a wide range of capabilities for 3D patterning of glass substrates with submicron accuracies. One of the challenges associated with this manufacturing process is that due to the small dimensions of the laser modified zone (voxel) in x, y, and z axis, the relative alignment of the laser voxel to the glass substrate in all three dimensions is critical. Furthermore, when the wafer or panel is placed onto the chuck within the laser writing tool, small angular variations typically occur due to variations such as the wafer or glass thickness or coplanarity of the surfaces. Therefore, to maintain x, y, and z axis alignment to the wafer, accurate angular alignment is required to allow for compensation of the tilt of the wafer during the fabrication process. The techniques discussed herein provide for one step on-the-fly angular alignment information of the wafer or panel with respect to the laser micromachining axes for improved processing accuracy.

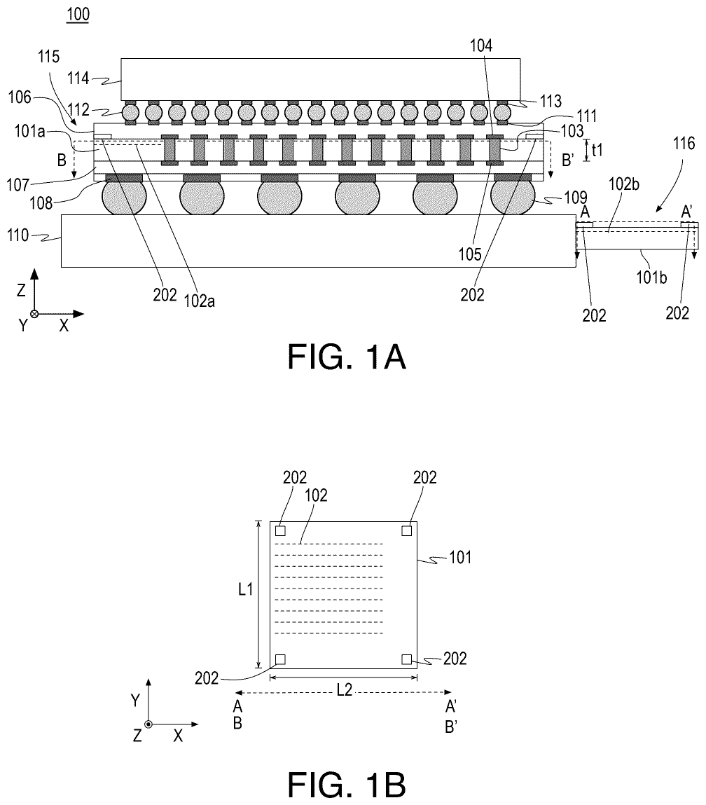

FIG. 1A illustrates a cross-sectional side view of an integrated circuit system 100 having one or more angular alignment features on a glass substrate, arranged in accordance with some embodiments of the disclosure. FIG. 1B illustrates a top-down cross-sectional view of a glass substrate component including angular alignment features and optical features such as waveguides formed within the glass substrate, arranged in accordance with some embodiments of the disclosure. For example, either glass substrate 101a or glass substrate 101b may have the illustrated top-down cross-sectional view of FIG. 1B.

As shown in FIG. 1A, integrated circuit system 100 includes at least one integrated circuit device 114 electrically attached to an electronic substrate 115. Integrated circuit system 100 may be characterized as an integrated circuit assembly, package, or device. Electronic substrate 115 may be any appropriate structure, including, but not limited to, an interposer. Electronic substrate 115 includes a glass substrate 101a, which may be characterized as a layer of glass, and any number of optical waveguides 102a or similar optical features formed within glass substrate 101a using the techniques discussed herein. Although discussed herein with respect to optical waveguides 102a, glass substrate 101a may include any features formed using laser inscription techniques. As discussed in further detail herein below, such laser inscription using, for example, ultra-short pulse laser inscription accuracy may be improved using angular alignment features 202.

As shown, in some embodiments, in addition or in the alternative, a glass substrate 101b including optical waveguides 102b may be deployed in integrated circuit system 100. For example, glass substrate 101b and optical waveguides 102b may be part of an edge routing or edge coupling device 116. In either case, angular alignment features 202 may be used to improve the accuracy and processing in implementing optical waveguides 102a, 102b within glass substrate 101a, 101b.

Glass substrates 101a, 101b, which are also labeled as glass substrate 101 herein, may have any suitable characteristics. In some embodiments, glass substrate 101 is or includes a layer of glass (e.g., a glass core). In some embodiments, glass substrate 101 is an amorphous solid glass layer. In some embodiments, glass substrate 101 is or includes a layer of glass, which, for example, is one of aluminosilicate, borosilicate, alumino-borosilicate, silica, and fused silica. The layer of glass may include one or more of additives including Al₂O₃, B₂O₃, MgO, CaO, SrO, BaO, SnO₂, Na₂O, K₂O, P₂O₃, ZrO₂, Li₂O, Ti, or Zn. For example, the layer of glass may include an additive including one or more of aluminum, boron, magnesium, calcium, strontium, barium, tin, sodium, potassium, phosphorous, zirconium, lithium, titanium, or zinc. In some embodiments, the layer of glass may include silicon and oxygen and one or more of aluminum, boron, magnesium, calcium, strontium, barium, tin, sodium, potassium, phosphorous, zirconium, lithium, titanium, and zinc. In some embodiments, the layer of glass includes at least 23 percent silicon and at least 26 percent oxygen by weight, and further includes at least 5 percent aluminum by weight. In some embodiments, the layer of glass is rectangular in shape in plan view. However, other shapes may be used. In some embodiments, glass substrate 101 is absent any organic adhesive or other organic material.

In some embodiments, glass substrate 101 has a thickness t1 in the range of 50 microns to 1.4 mm (i.e., in the z-dimension). In some embodiments, glass substrate 101 is a multi-layer glass substrate (e.g., a coreless substrate) where a glass layer of glass substrate 101 has a thickness in the range of about 25 microns to 50 microns. As shown in FIG. 1B, in some embodiments, glass substrate 101 has a first length L1 and a second length L2 (or a width). In some embodiments, first length L1 is in the range of about 10 mm to 250 mm and second length L2 is in the range of about 10 mm to 250 mm. For example, glass substrate 101 may have dimensions in the range of about 10 mm×10 mm to 250 mm×250 mm. Other lateral lengths and thicknesses may be used. In some embodiments, a glass core or a glass layer of glass substrate 101 is a rectangular prism volume with sections (e.g., vias) removed and filled with other materials (e.g., metal) to form through glass vias 103.

In some embodiments, electronic substrate 115 may further include dielectric layers 106, 107 built up over a glass core. However, such dielectric layers 106, 107 may not be deployed in some contexts. Dielectric layers 106, 107 may each include, for example, a plurality of dielectric material layers, which may include build-up films and/or solder resist layers, and may be composed of an appropriate dielectric material, including, but not limited to, bismalcimide triazine resin, fire retardant grade 4 material, polyimide material, silica filled epoxy material, glass reinforced epoxy material, and the like, as well as low-k and ultra-low-k dielectrics (dielectric constants less than about 3.6), including, but not limited to, carbon doped dielectrics, fluorine doped dielectrics, porous dielectrics, organic polymeric dielectrics, and the like.

Electronic substrate 115 may further include conductive routes inclusive of bond pads 104, 105 and through glass vias 103 as well as routing that extends through the dielectric layers 106, 107 (not shown). The conductive routes may be a combination of conductive traces and conductive vias, which may be made of any appropriate conductive material, including but not limited to, metals, such as copper, silver, nickel, gold, and aluminum, alloys thereof, and the like. In some embodiments, electronic substrate 115 may further include active and/or passive devices.

Integrated circuit device 114 may be any appropriate device, including, but not limited to, a microprocessor, a chipset, a graphics device, a wireless device, a memory device, an application specific integrated circuit, combinations thereof, stacks thereof, or the like. Integrated circuit device 114 may be characterized as a chiplet and integrated circuit system 100 may include any number of such chiplets or integrated circuit devices interconnected by the discussed conductive routing and or interconnect bridge devices. Integrated circuit device 114 may be a monolithic die or a die stack including two or more vertical levels of dice stacked on top of each other, and may include additional materials, such as a mold compound, between at least two of the dice. Integrated circuit device 114 may be electrically attached to the electronic substrate 115 by device-to-substrate interconnects 112, which couple and extend between bond pads 111, 113. Device-to-substrate interconnects 112 may be any appropriate electrically conductive material or structure, including, but not limited to, solder balls, metal bumps or pillars, and metal filled epoxies. In some embodiments, device-to-substrate interconnects 112 are surrounded by an underfill material (not shown).

In some embodiments, electronic substrate 115 is electrically coupled to a carrier substrate 110, such as a board or motherboard. Carrier substrate 110 may include a number of dielectric material layers and conductive routes or metallization layers and vias extending through the carrier substrate 110, such that the one conductive route extend between bond pads 105 to bond pads 108, and on to external components (not shown). Electronic substrate is electrically attached to carrier substrate 110 with external interconnects 109 extending between conductive bond pads 108 of electronic substrate 115 and bond pads or other conductive structures or features of carrier substrate 110.

As shown, in some embodiments, edge coupling device 116 is optically coupled to carrier substrate 110 at a side of carrier substrate 110. In other embodiments, edge coupling device 116 is mounted on carrier substrate 110 and is optically coupled to another mounted device. Such as electronic substrate 115 or integrated circuit device 114. A variety of architectures are available. In any event, edge coupling device 116 or a surface mounted coupling device 116 includes optical waveguides 102b or similar features within glass substrate 101b such that optical waveguides 102b using laser scribing as discussed herein below. Such laser inscription processing is improved using angular alignment features 202.

Although illustrated with respect to glass substrate 101a and/or glass substrate 101b including optical waveguides 102a, 102b or similar optical features, the discussed techniques may be deployed in any suitable context deploying a glass substrate inscribed with features using, for example, an ultra-short pulse laser such that the glass substrate includes inscribed features and angular alignment features 202.

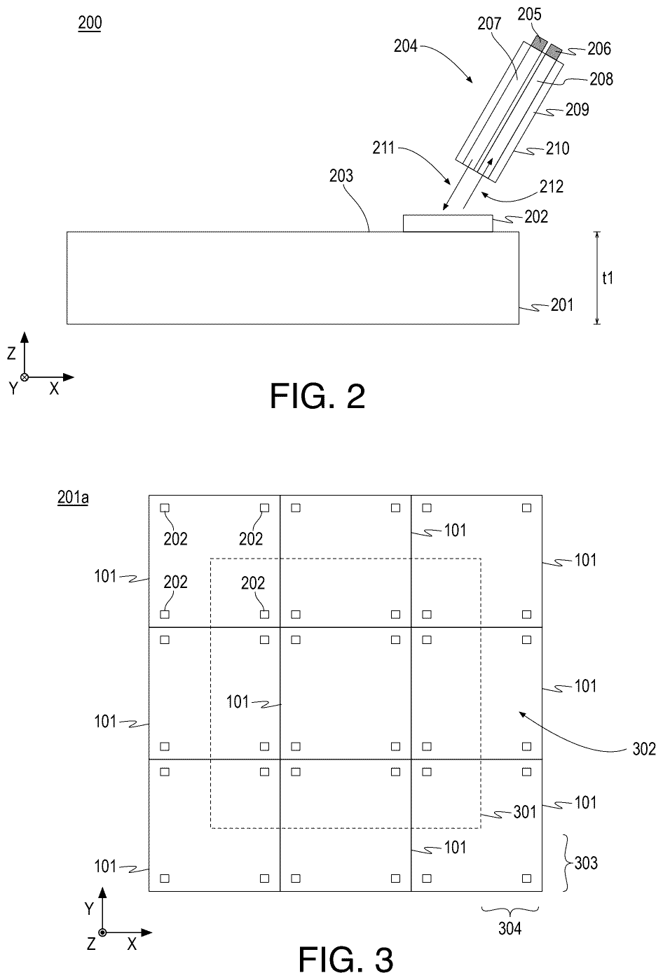

FIG. 2 illustrates a side view of angled optical probing 200 of a substrate workpiece 201 including angular alignment features 202, arranged in accordance with some embodiments of the disclosure. As shown in FIG. 2, substrate workpiece 201 includes angular alignment features 202 on or within a top surface 203 of substrate workpiece 201. The details of angular alignment features 202 are discussed further herein below. Substrate workpiece 201 may have any characteristics discussed with respect to glass substrate 101. For example, substrate workpiece 201 may be a substrate from which any number of substrate components (e.g., glass substrate 101a, 101b) may be segmented after processing. For example, substrate workpiece 201 may include any suitable substrate material or material layers that may be inscribed with 3D laser processing to form features therein. Substrate workpiece 201 may include any material or materials discussed herein with respect to glass substrate 101, for example, and may have any suitable format or architecture. In some embodiments, glass substrate 101 is a glass panel such as a 500 mm×500 mm glass carrier panel. In some embodiments, the substrate is a glass wafer such as a 300 mm wafer. However, other substrate formats may be used.

Substrate workpiece 201 is mounted within a laser inscription tool (e.g., a 3D ultra-short pulse laser scribe tool), as illustrated further herein below. As shown, angular alignment features 202 on or within substrate workpiece 201 are each probed by an optical probe 204. In some embodiments, other devices have been previously formed in substrate workpiece 201 (e.g., through glass vias) or previously mounted to substrate workpiece 201 (e.g., chiplets, interconnect bridges, passive or active devices, etc.). As shown, substrate workpiece 201 (e.g., a glass wafer or panel) includes one or more angular alignment features 202 (e.g., optical alignment features or structures) that may be alongside chiplets or other features or devices. Angular alignment features 202 provide for angular alignment for a writing laser beam (e.g., for writing waveguides or other features), as illustrated herein below.

Angular alignment features 202 on or within substrate workpiece 201 are each probed by optical probe 204 to determine a local angle of top surface 203 of substrate workpiece 201. As shown, in some embodiments, optical probe 204 includes a light source 205, a photodetector 206, fiber cores 207, 208, optical fiber ribbon 209, and a housing 210. Light source 205 provides light of any suitable spectrum and wavelength through fiber cores 207 and incident on angular alignment feature 202 to provide angled incident light 211. In the illustrated embodiment, angular alignment feature 202 is retro-reflective such that angled incident light 211 is reflected back at the same or similar angle as to that of angled incident light 211 such that reflected light 212 is received by fiber cores 208 and delivered to photodetector 206.

In some embodiments, optical probe 204 includes two co-planar arrays. The first array is implemented as light source 205 and includes, for example, an array of micro-LEDs (light emitting diodes), an array of VCSELs (vertical-cavity surface-emitting lasers), or an array of lasers. The second array is implemented as photodetector 206 and includes an array of individual photodetectors to provide the functionality of photodetector 206. In some embodiments, photodetector 206 includes or is coupled to a spectrometer to evaluate a light spectrum as discussed herein. As shown, the co-planar arrays may be attached to a multicore optical fiber including fiber cores 207, 208. In some embodiments, a first set of the cores of the multicore optical fiber (e.g., fiber cores 207) are dedicated to sending light from light source 205 (e.g., micro-LED, VCSEL array) to substrate workpiece 201, and a second set of the fiber cores (e.g., fiber cores 208) are dedicated to couple light reflected from wafer optical structures back into photodetector 206. Although illustrated with respect to fiber optic systems, bulk optics may be used inclusive of laser sources and barrel optics and the like. In operation, optical probe 204 may detect angular alignment feature 202 using reflected light 212, and register the location reached by the x- and y-motors the stage on which substrate workpiece 201 is mounted. Determination of the angle of top surface 203 of substrate workpiece 201 is discussed herein below.

FIG. 3 illustrates a top-down view of an example substrate workpiece 201a including angular alignment features 202 within a central region 301 and a perimeter region 302 of substrate workpiece 201a, arranged in accordance with some embodiments of the disclosure. Angular alignment features 202 may be distributed across the area of a substrate workpiece such as substrate workpiece 201a using any suitable techniques. Additional angular alignment features 202 increase the accuracy of the mapping of top surface 203 of substrate workpiece 201 at the expense of increased processing duration. In the example of FIG. 3, substrate workpiece 201a is to eventually be segmented into a number of glass substrates 101, which will be individually deployed in a device. FIG. 3 illustrates nine glass substrates 101, however, any number may be segmented from substrate workpiece 201a. Prior to such segmentation, substrate workpiece 201a is processed inclusive of 3D laser scribing as discussed herein.

In the embodiment of FIG. 3, angular alignment features 202 are located at a corner of each of glass substrates 101 such that a number of angular alignment features 202 are within central region 301. By including angular alignment features 202 at each corner of glass substrates 101, an accurate surface angle may be determined for each of glass substrates 101. Perimeter region 302 and central region 301 may be defined such that perimeter region 302 includes a length 303 of the total length (in the y-direction) of substrate workpiece 201a and a width 304 of the total width (in the x-direction) such that each is a particular fraction (e.g., 10%) of the total length or width. In some embodiments, the fraction of length 303 to total length and the fraction of width 304 to total width is 10%. In some embodiments, the fraction of length 303 to total length and the fraction of width 304 to total width is 15%. In some embodiments, the fraction of length 303 to total length and the fraction of width 304 to total width is 20%. When segmented, each of glass substrates 101 has one of angular alignment features 202 at a corner thereof.

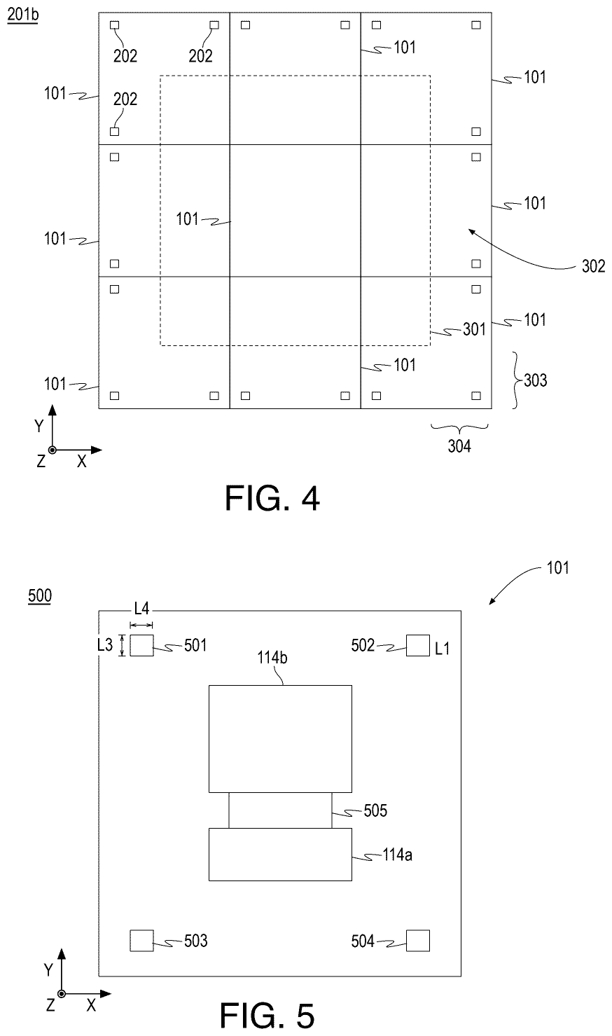

FIG. 4 illustrates a top-down view of an example substrate workpiece 201b including angular alignment features 202 only within perimeter region 302 of substrate workpiece 201b, arranged in accordance with some embodiments of the disclosure. As discussed, angular alignment features 202 may be distributed across the area of a substrate workpiece such as substrate workpiece 201b using any suitable techniques. In the example of FIG. 4, substrate workpiece 201b only including angular alignment features 202 within perimeter region 302 may provide for a relatively fast processing time while still attaining enough information to accurately map the top surface of substrate workpiece 201b.

Although illustrated with perimeter region 302 angular alignment features 202 at the corners of glass substrates 101, perimeter region 302 angular alignment features 202 may be distributed around perimeter region 302 using any suitable technique or techniques. In some embodiments, perimeter region 302 angular alignment features 202 are only at the four corners of substrate workpiece 201b. In some embodiments, perimeter region 302 angular alignment features 202 are at the four corners of substrate workpiece 201b and the four mid-points of the edges of substrate workpiece 201b. In some embodiments, perimeter region 302 angular alignment features 202 are at the four corners of substrate workpiece 201b and arrayed equidistant from one another along the edges of substrate workpiece 201b such that 2, 3, 4, or more additional angular alignment features 202 are provided along each edge (for a total of 12, 16, 20, or more angular alignment features 202 on substrate workpiece 201b). In some embodiments, as shown, perimeter region 302 angular alignment features 202 are at the perimeter edges of each of glass substrates 101.

In the embodiment of FIG. 4, when segmented, each of glass substrates 101 may have a different arrangement of angular alignment features 202. For example, the upper-left, upper-right, lower-left, and lower-right glass substrates 101 each includes 3 angular alignment features 202 at corners thereof. The upper-middle, lower-middle, middle-left, and middle-right glass substrates 101 each includes 2 angular alignment features 202 at corners thereof. Other arrangements of angular alignment features 202 will be evident depending on the arrangement of angular alignment features 202 within each of glass substrates 101.

FIG. 5 illustrates a top-down view of an example integrated circuit system 500 including angular alignment features 501, 502, 503, 504 at each corner of glass substrate 101, arranged in accordance with some embodiments of the disclosure. For example, integrated circuit system 500 may be deployed in the context of integrated circuit system 100, with integrated circuit devices 114a, 114b mounted to glass substrate 101, which is in turn mounted to carrier substrate 110. Furthermore, integrated circuit system 500 includes an interconnect bridge 505 that may interconnect integrated circuit devices 114a, 114b. In some embodiments, interconnect bridge 505 is a relatively small die that include multiple routing layers of conductive interconnects to electrically couple integrated circuit devices 114a, 114b.

As shown, in some embodiments, angular alignment features 501, 502, 503, 504 may be characterized as dot angular alignment features as they have substantially the same length L3 and width L4, which are relatively small compared to the full area of glass substrate 101. Length L3 and width L4 may be any suitable dimensions. In some embodiments, length L3 and width LA are in the range of 1 to 10 microns. In some embodiments, length L3 and width L4 are not more than 10 microns.

In the illustrated example, four angular alignment features 501, 502, 503, 504 are positioned at the four corners of glass substrate 101. However, as discussed herein, any number of angular alignment features 501, 502, 503, 504 may be positioned in any manner. In some embodiments, angular alignment features 501, 502, 503, 504 are positioned at the midpoints of the edges of glass substrate 101. In some embodiments, angular alignment features 501, 502, 503, 504 are positioned at the corners and midpoints of the edges of glass substrate 101. In some embodiments, one or more angular alignment features 501, 502, 503, 504 are positioned within a central region (not shown) of glass substrate 101 such that the central region is defined as discussed with respect to FIG. 3. Notably, one or more or portions of angular alignment features 501, 502, 503, 504 may be buried by a build-up layer on glass substrate 101 or any of integrated circuit devices 114a, 114b or interconnect bridge 505 in integrated circuit system 500.

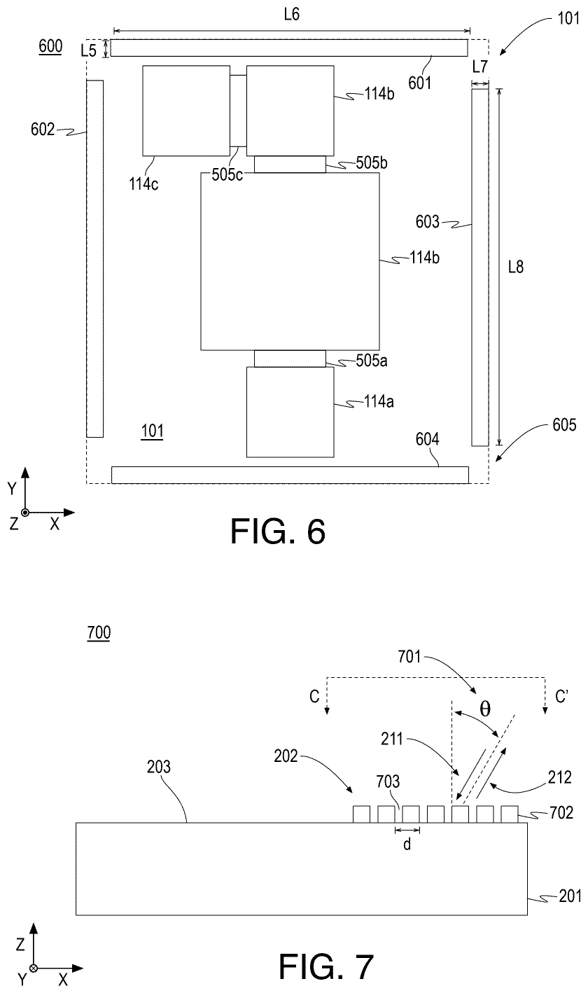

FIG. 6 illustrates a top-down view of an example integrated circuit system 600 including angular alignment features 601, 602, 603, 604 along each edge of glass substrate 101, arranged in accordance with some embodiments of the disclosure. As with integrated circuit system 500, integrated circuit system 600 may be deployed in the context of integrated circuit system 100, with integrated circuit devices 114a, 114b, 114c mounted to glass substrate 101, which is in turn mounted to carrier substrate 110. Integrated circuit devices 114a, 114b, 114c may be interconnected by interconnect bridges 505a, 505b, 505c. In some embodiments, interconnect bridges 505a, 505b, 505c are relatively small dies having multiple routing layers to electrically interconnect integrated circuit devices 114a, 114b, 114c.

As shown, in some embodiments, angular alignment features 601, 602, 603, 604 may be characterized as line angular alignment features as they have a length L8 (or width L6) that is substantially longer than a width L7 (or length L5) of the feature. Length L8 (and width L6) and width L7 (and length L5) may be any suitable dimensions. In some embodiments, width L7 (and length L5) are in the range of 1 to 10 microns. In some embodiments, width L7 (and length L5) are not more than 10 microns. In some embodiments, length L8 (and width L6) are in the range of 10 to 100 mm or more. In some embodiments, length L8 (and width L6) are not less than 10 mm.

In the illustrated example, four angular alignment features 601, 602, 603, 604 are positioned along each edge of a perimeter 605 of glass substrate 101. However, any number of angular alignment features 601, 602, 603, 604 may be positioned in any manner. In some embodiments, two angular alignment features 601, 602 or two angular alignment features 603, 604 are deployed to find angular alignment measurements along adjacent and orthogonal edges. In some embodiments, two angular alignment features 601, 604 or two angular alignment features 602, 603 are deployed to find angular alignment measurements along adjacent and orthogonal edges. In some embodiments, one or more angular alignment features 601, 602, 603, 604 are positioned within a central region (not shown) of glass substrate 101 such that the central region is defined as discussed with respect to FIG. 3. As with integrated circuit system 500, one or more or portions of angular alignment features 601, 602, 603, 604 may be buried by a build-up layer on glass substrate 101 or any of integrated circuit devices 114a, 114b, 114c or interconnect bridges 505a, 505b, 505c in integrated circuit system 600.

FIGS. 5 and 6 illustrate examples of glass substrates 101 fabricated with angular alignment features 202 such as dot or line angular alignment features. Angular alignment features 202 are placed around the package such as, for example, around the four sides of the package or at four corners of the package. Each angular alignment features 202 is designed to be optically reflective to reflect an incident optical beam from the top surface of glass substrates 101 (e.g., substrate workpiece 201) either in its original optical path or in a different but in a predetermined direction such that the reflected light can be collected by the optical probe positioned above the glass panel and analyzed for optical alignment.

As discussed, each angular alignment features 202 (or optical alignment mark) may be designed to reflect incident light back in a retro-reflection mode or to reflect light to a predetermined known direction. In the latter non-retro-reflection design, a separate optical receiver is positioned above substrate workpiece 201 (refer to FIG. 2) and is used to receive and collect the reflected probe beam for optical alignment. When each angular alignment feature 202 mark is retro-reflective, optical probe 204 can use the same optical waveguide such as a fiber that delivers the probe beam to the glass panel to collect the reflected probe beam to an optical detector coupled to the optical waveguide. The optical reflection of an alignment mark is designed to be much stronger than optical reflection or scattering at other parts of the glass panel. Under this design, the reflection from angular alignment feature 202 indicates whether the probe beam hits an alignment mark and the strength of reflection indicates whether the optical probe is properly aligned with reference to the optical alignment mark.

FIG. 7 illustrates a side view of retro-reflected angled optical probing 700 of a substrate workpiece 201 similar to that of FIG. 2, arranged in accordance with some embodiments of the disclosure. As shown in FIG. 7, substrate workpiece 201 includes angular alignment features 202 on or within a top surface 203 of substrate workpiece 201. For example, angular alignment features 202 are on or within a layer of glass of substrate workpiece 201. In some embodiments, angular alignment features 202 include an angular alignment grating to reflect a selected spectrum of light incident on the angular alignment grating at an angle relative to top surface 203 of the layer of glass. As shown, in some embodiments, the angular alignment grating is to retro-reflect the selected spectrum of light incident on the angular alignment grating at the angle. In some embodiments, angular alignment features 202 include a Littrow grating.

Angular alignment features 202 may include any structures or features to provide such characteristics. In some embodiments, angular alignment features 202 include a number of structures 702 that extend above top surface 203 and such that structures 702 are separated by openings 703 therebetween. In some embodiments, openings 703 may later be filled by build-up layers or other materials. Structures 702 may be formed from any materials such as metals or dielectric materials using any suitable technique or techniques such as deposition, lithography, and etch techniques.

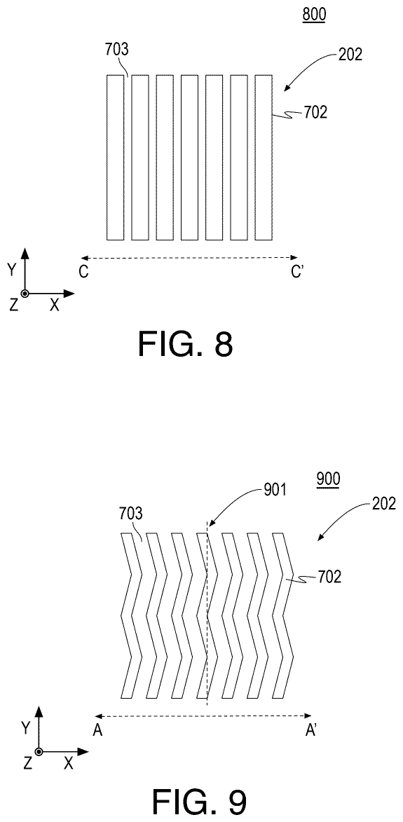

FIG. 8 illustrates a top-down view of an example linear array layout 800 of angular alignment features 202, arranged in accordance with some embodiments of the disclosure. As shown in FIG. 8, in some embodiments, structures 702 extend along top surface 203 of substrate workpiece 201 and are separated by openings 703 such that structures 702 and openings 703 are substantially linear. In some embodiments, angular alignment features 202 include structures 702 that have an aspect ratio in plan view of not less than 10 to 1. In some embodiments, angular alignment features 202 include structures 702 that extend in the y-dimension (as shown), the x-dimension, or both.

FIG. 9 illustrates a top-down view of an example serpentine array layout 900 of angular alignment features 202, arranged in accordance with some embodiments of the disclosure. As shown in FIG. 9, in some embodiments, structures 702 extend along top surface 203 of substrate workpiece 201 and are separated by openings 703 such that structures 702 and openings 703 have a serpentine pattern with some segments extending away from a centerline 901 of each of structures 702 and some segments extending toward centerline 901 in an alternating serpentine pattern. As with linear array layout 800, in some embodiments, angular alignment features 202 include structures 702 that extend in the y-dimension (as shown), the x-dimension, or both.

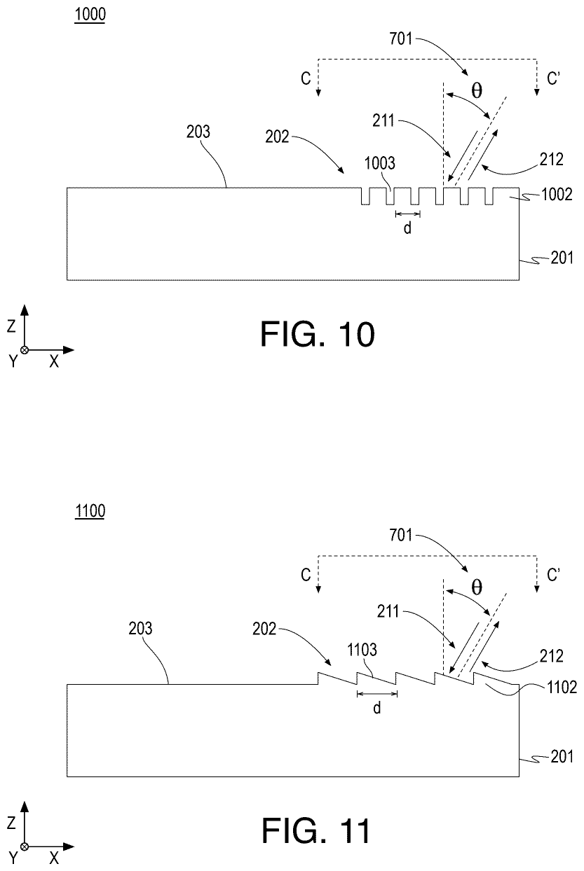

FIG. 10 illustrates a side view of retro-reflected angled optical probing 1000 of a substrate workpiece 201 having angular alignment features 202 that are formed within top surface 203 of substrate workpiece 201, arranged in accordance with some embodiments of the disclosure. As shown in FIG. 10, substrate workpiece 201 includes angular alignment features 202 within top surface 203 of substrate workpiece 201. For example, angular alignment features 202 may be formed within a layer of glass of substrate workpiece 201. In some embodiments, angular alignment features 202 include an angular alignment grating to reflect a selected spectrum of light incident on the angular alignment grating at an angle relative to top surface 203 of the layer of glass. As shown, in some embodiments, the angular alignment grating is to retro-reflect the selected spectrum of light incident on the angular alignment grating at the angle.

Angular alignment features 202 may again include any structures or features to provide such reflective characteristics. In some embodiments, angular alignment features 202 include a number of structures 1002 that have a top surface substantially coplanar with top surface 203 and openings 1003 between structures 1002 and extending into top surface 203. In some embodiments, openings 1003 may later be filled by build-up layers or other materials. Structures 1002 may be the same material as the bulk material of substrate workpiece 201, and structures 1002 and openings 1003 may be formed using any suitable technique or techniques such as lithography and etch techniques, laser ablation techniques, or others.

FIG. 11 illustrates a side view of retro-reflected angled optical probing 1100 of a substrate workpiece 201 with angular alignment features 202 having angular surfaces that are formed within top surface 203 of substrate workpiece 201, arranged in accordance with some embodiments of the disclosure. As shown in FIG. 11, substrate workpiece 201 includes angular alignment features 202 on or at least partially within top surface 203 of substrate workpiece 201. For example, angular alignment features 202 may be formed on or within a layer of glass of substrate workpiece 201. In some embodiments, angular alignment features 202 include an angular alignment grating to reflect a selected spectrum of light incident on the angular alignment grating at an angle relative to top surface 203 of the layer of glass. As shown, in some embodiments, the angular alignment grating is to retro-reflect the selected spectrum of light incident on the angular alignment grating at the angle.

Angular alignment features 202 may again include any structures or features to provide such reflective characteristics. In some embodiments, angular alignment features 202 include a number of structures 1102 that each have an angled top surface 1103 relative to top surface 203 of substrate workpiece. Structures 1102 may be the same material as the bulk material of substrate workpiece 201 or they may be applied on top surface 203 of substrate workpiece 201, and structures 1002 and openings 1003 may be formed using any suitable technique or techniques such as application of a pre-form, lithography and etch techniques, laser ablation techniques, or others.

Angular alignment features 202 as discussed with respect to FIGS. 7, 10, and 11 may have any top-down layout as discussed with respect to FIGS. 8 and 9 and may be distributed on top surface of substrate workpiece 201 and glass substrates 101 in any manner discussed herein.

Returning now to FIG. 7 and with reference to similar features in FIGS. 10 and 11, angled incident light 211 is emitted from light source 205 (refer to FIG. 2) and applied at an angle 701 (angle θ) relative to top surface 203 of substrate workpiece 201. In some embodiments, reflected light 212 is retro-reflected from angular alignment features 202 back to photodetector 206 or other detector device at the same angle 701 (angle θ) relative to top surface 203. Alignment of top surface 203 of substrate workpiece 201 may then be performed using any suitable techniques.

In some embodiments, a spectrum of light is emitted and received. For example, a broad band of light (including many wavelengths) is shown onto the top surface at an angle. The received spectrum is then analyzed to determine a peak wavelength and the peak wavelength is translated to determine angle 701 (angle θ). For example, a Littrow grating may be used for angular alignment features 202. In some embodiments, the wavelength components of the received light are analyzed, with the shape of the received spectrum having a peak at a particular wavelength. For example, a Littrow grating operates to produce a retro-reflection under the Littrow condition shown in the following Equation (1):

$$d = m \cdot λ / ( 2 \cdot n \cdot sin θ ) \qquad ( 1 )$$

where m is an integer for the diffraction order, d is the pitch of the grating (refer to FIG. 7), λ is the wavelength (e.g., peak wavelength), n is the effective index of the fiber probe, and θ is angle 701 (i.e., the angle of the fiber probe with respect to the normal direction of top surface 203).

For a given angular alignment feature 202 design (i.e., d and λ) and probe design (i.e., n), the angle corresponding to the detected peak angle may then be determined as follows in Equation (2):

$$θ = {sin}^{- 1} ( \frac{m \cdot λ}{2 \cdot n \cdot d} ) \qquad ( 2 )$$

where θ is angle 701 (i.e., the angle of the fiber probe with respect to the normal direction of top surface 203). Thereby, the probe can detect any angular misalignment of top surface 203 (or a local region at angular alignment feature 202) of substrate workpiece 201 by filtering by wavelength.

Once angle 701 (angle θ) is known, the angle relative to the inscription laser beam may then be determined based on filtering by wavelength as discussed herein. The local region angle at each angular alignment feature 202 may then be combined with other angles at other angular alignment features 202 to provide, for example, a mapping of the surface of substrate workpiece 201. This mapping may then be deployed to alter the relative position of an intended laser inscription voxel within substrate workpiece 201 for improved accuracy. For example, the actual surface with misalignment, imperfections, and so on may be compensated for such that the resultant 3D written feature (i.e., by the working laser beam) is accurately formed in substrate workpiece 201. In some embodiments, the mapping of the surface of substrate is deployed as a rotation matrix that a scribe tool may use during runtime for use as an adjusted frame of reference. However, any mapping and voxel location adjustments may be made based on the surface mapping such as stage tilt operations, laser or laser optics movements, or the like.

This compensation may be performed using any suitable technique or techniques. In some embodiments, the inscription voxel location within the glass substrate is based on adjustment of a location of a point of focus from the laser source and the lens system. For example, the adjustment may be made in a software mapping provide to the 3D laser and lens system. In some embodiments, the inscription voxel location within the glass substrate is adjusted based on the angle of the portion of the top surface of the glass substrate, such that the adjustment based on adjustment of one or more of location and/or orientation of the substrate holder, or location and/or orientation of the laser source and/or the lens system. For example, the compensation may be made by physical movement of the laser source and lens system relative to the substrate workpiece.

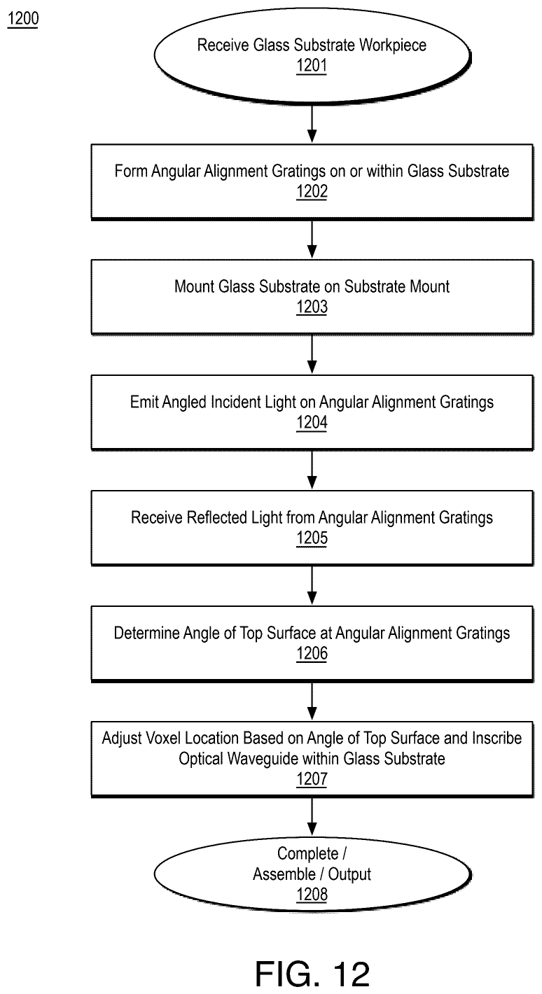

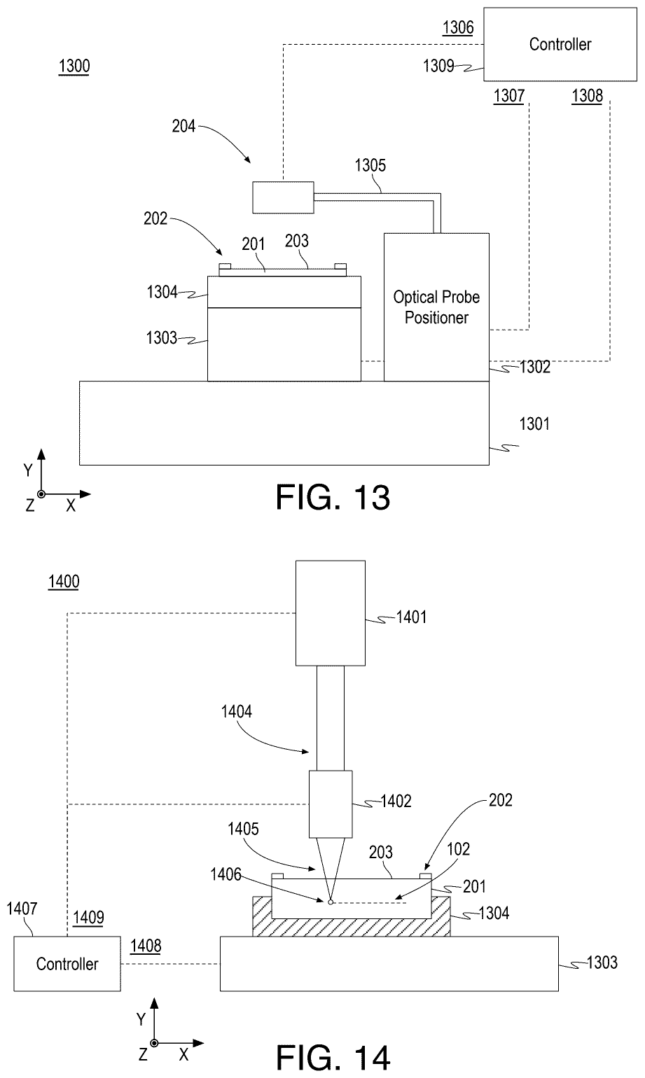

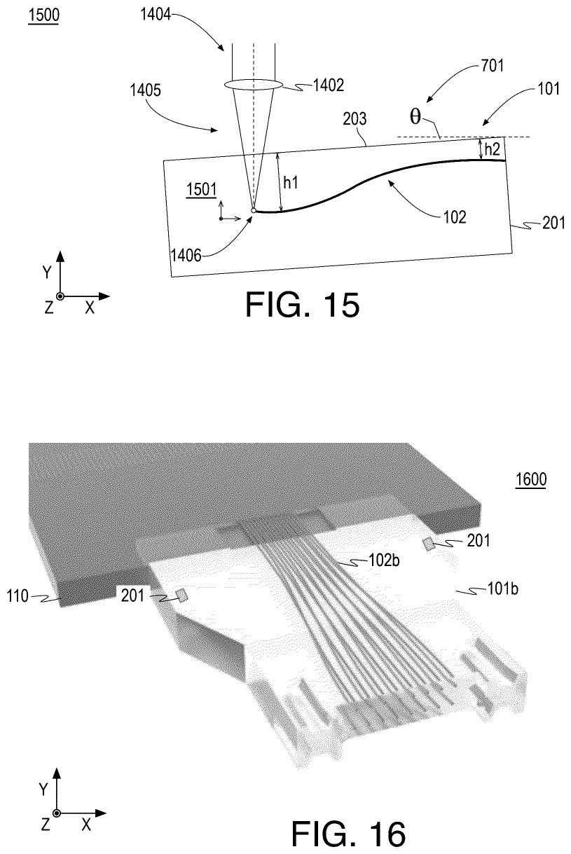

FIG. 12 is a flow diagram illustrating methods 1200 for forming angular alignment features and using the angular alignment features to align a glass substrate for 3D laser scribing, arranged in accordance with some embodiments of the disclosure. FIG. 13 is a diagram of an example system 1300 using angular alignment features to map surface angles of a glass substrate, arranged in accordance with some embodiments of the disclosure. FIG. 14 is a diagram of an example system 1400 for using adjustments based on the angular alignment features to align and 3D laser scribe a glass substrate, arranged in accordance with some embodiments of the disclosure. FIG. 15 is a diagram of exemplary on-the-fly 3D laser scribing adjustments 1500 based on angular alignment features, arranged in accordance with some embodiments of the disclosure.

Methods 1200 begin at input operation 1201, where a workpiece including a layer of glass is received for processing. The workpiece includes any suitable substrate material or material layers on or within which 3D features may be inscribed. The substrate may include any materials such as glass materials discussed herein and may have any suitable format or architecture. In some embodiments, the substrate is a glass panel such as a 500 mm×510 mm glass carrier panel. In some embodiments, the substrate is a silicon wafer such as a 300 mm silicon wafer.

Processing continues at operation 1202, where angular alignment features are formed on or within the glass substrate. In some embodiments, angular alignment gratings are formed of the same material as the bulk glass substrate by removing material between the resultant grating structures (refer to FIG. 10) to form opening such as trench openings. In some embodiments, the trench openings are formed using patterning and etch techniques. However, other techniques such as laser scribing, mechanical scribing, or the like may be deployed. In some embodiments, angular alignment gratings are formed by applying a material or materials on the bulk glass substrate (refer to FIG. 7) with openings between the applied material or materials. Such structures may be formed from any materials such as metals or dielectric materials. The structures may be formed using any suitable technique or techniques such as deposition, lithography, and etch techniques. However, other material removal techniques may be deployed. The angular alignment gratings may be positioned on the glass substrate in any manner to provide localized mappings of the angle of the top surface of the glass substrate.

Processing continues at operation 1203, where the glass substrate including the angular alignment features or gratings is mounted on a substrate holder such as a chuck or other work surface. The glass substrate may be mounted for angular alignment feature evaluation only or the glass substrate may be mounted for angular alignment feature evaluation and subsequent 3D writing by a working laser. For example, the same tool or system may provide both functions or they may be performed by different tools or systems.

As shown in FIG. 13, system 1300 is used to evaluate angular alignment gratings and/or make adjustments based on evaluation of angular alignment gratings. System 1300 includes a support base 1301, an optical probe positioner 1302, optical probe 204 coupled to optical probe positioner 1302 by a working arm 1305 or other actuation device, a substrate positioner 1303 (e.g., a panel positioner), and a substrate holder 1304 (e.g., a panel holder or chuck).

As shown in FIG. 13, substrate holder 1304 is used to hold substrate workpiece 201 having any number of glass substrates 101. Substrate workpiece 201 may further include other package devices such as integrated circuit devices (not shown in FIG. 13). For example, glass substrates 101 may be packages patterned to include angular alignment feature 202 that reflect incident light as discussed herein. Substrate holder 1304 may be any suitable holding device such as a vacuum chuck.

Substrate positioner 1303 is engaged with substrate holder 1304 to control positions and orientations of substrate workpiece 201 based on control signals 1308 received from a controller 1309. Substrate positioner 1303 may be any suitable device such as a stage driven by motors to position the stage in x, y, z and to rotate the stage, as is known in the art. Optical probe 204 is used to deliver a probe beam of emitted light to top surface 203 of substrate workpiece 201 (e.g., to a panel surface). Optical probe 204 may be controlled by control signals 1306 received from controller 1309. The probe beam is at an incident angle and optical probe receives optical reflection of the probe beam from substrate workpiece 201. Optical probe positioner 1302 is engaged to optical probe 204 to control the position of optical probe 204 based on control signals 1307 received from controller 1309. Controller 1309 is used to control substrate positioner 1303 and optical probe 204 in aligning optical probe 204 to a selected position on substrate workpiece 201 according to reflection of the probe beam from angular alignment features 202.

Returning to FIG. 2, processing continues at operation 1204, where angled incident light is emitted on an angular alignment feature or grating on or within the top surface of the glass substrate being processed. Processing continues at operation 1205, where reflected light from the angled incident light on the angular alignment feature or grating is received and at operation 1206, where an angle of at least a portion of the top surface of the glass substrate is determined based on the reflected light. In some embodiments, the emitted angled incident light includes a spectrum of light, and determining the angle of the portion of the top surface of the glass substrate is based on a detected peak wavelength in the reflected light. For example, the detected peak wavelength may be translated to the angle based on Equation (2) above or a similar function defined by the grating deployed. In some embodiments, the reflected light is retro-reflected from the angled incident light. However, in some embodiments, the reflected light is non-retro-reflected from the angled incident light. Any angular alignment feature or grating discussed herein may be deployed in methods 1200.

Based on one or more substrate angle measurements, a mapping of the substrate may be made. The mapping may then be used to adjust 3D writing of the glass substrate. Although discussed with respect to angular measurement and mapping followed by 3D writing, such processing may be performed in parallel.

Processing continues at operation 1207, where a 3D writing voxel location within the glass substrate is adjusted based on the angle of the portion of the top surface of the glass substrate. The voxel location may be adjusted using any suitable technique or techniques. In some embodiments, the voxel location within the glass substrate is adjusted based on the angle of the portion of the top surface of the glass substrate, such that the adjustment is made by moving the location and/or orientation of the substrate holder holding the glass substrate, or moving location and/or orientation of the laser source and/or the lens system being used to perform the 3D writing. In some embodiments, the resultant modifications to the glass are selectively etched.

As shown in FIG. 14, system 1400 is used to make adjustments based on the angular alignment features to align and 3D laser scribe a glass substrate. In some embodiments, the components of system 1300 and the components of system 1400 may be combined into the same system. In other embodiments separate systems 1300, 1400 are used. Like components between systems 1300, 1400 are illustrated and discussed with respect to like feature numbers. As shown, system 1400 includes substrate holder 1304 to receive substrate workpiece 201 and substrate positioner 1303 to control positions and orientations of substrate workpiece 201. System 1400 further includes a laser source 1401 to provide a laser beam 1404 to laser optics 1402. Laser optics 1402 focus laser beam 1404 to a focused laser beam 1405, which comes to a point of focus at voxel 1406. As shown, voxel 1406 modifies the glass of substrate workpiece 201 to form a waveguide 102 or similar feature.

For example, system 1400 is used to form optical structures and alignment holes in a material of a body such as a glass layer or substrate of substrate workpiece 201. System 1400 includes laser source 1401 that has an associated acousto-optic modulator (not shown) that can modulate a pulse train from laser source 1401. The laser or laser source 1401 also has an external compressor stage (not shown), for emitting a beam of laser radiation/beam such as laser beam 1404 and focused laser beam 1405 for use in forming optical structures or holes in a radiation sensitive material, for example a suitable glass or crystal material of substrate workpiece 201.

FIG. 15 is a diagram of exemplary on-the-fly 3D laser scribing adjustments 1500 based on angular alignment features, arranged in accordance with some embodiments of the disclosure. As shown in FIG. 15, voxel 1406 may be modified 1501 in x, y, z based on measured angle 701 (angle θ) of top surface 203 to reduce the height discrepancy between height h1 and height h2 (and lateral discrepancies, not shown) as waveguide 102 or similar feature is formed in substrate workpiece 201.

Notably, for advanced co-packaged photonics applications, the use of 3D optical waveguides such as waveguides 102 in glass substrates allows for high density optical routing of signals from chiplet to chiplet, and chiplet to package edge, and so on. The 3D nature allows for high channel densities, multilayer waveguide circuits, and integration with high precision 3D micromachined structures. The fabrication of 3D waveguides such as waveguides 102 and other features such as 3D laser micromachined structures on and within substrate workpiece 201 (e.g., at the wafer and panel level) requires tight alignment to top surface 203 due to the small dimensions of the laser modified zone (voxel 1406) in x, y, and z axis, typically in the region of a few microns in size.

When substrate workpiece 201 is placed onto substrate holder 1304 (e.g., a chuck within) system 1400 (e.g., a laser writing tool), small angular variations typically occur due to variations such as substrate workpiece 201 or coplanarity of the surfaces. Therefore, to maintain x, y, and z axis alignment to substrate workpiece 201, accurate angular alignment is required to allow for compensation of the tilt of substrate workpiece 201 during the fabrication process. For example, since the laser voxel size of voxel 1406 is of the order of 1 micron in size, typical z-alignment accuracies required are approximately 0.5 microns, and with typical device sizes requiring waveguide lengths in the region of 10 mm, then local angular tilt accuracy required is of the order of 50 microradians.

In the context of system 1400, substrate workpiece 201 is carried in a sample space on substrate holder 1304 and substrate positioner 1303 (e.g., a stage structure) that can be moved under the control of a computer-based control unit such as controller 1407 using control signals 1408. Controller 1407 also controls operation of laser source 1401 and laser optics 1402 using control signals 1409. In operation, focused laser beam 1405 is focused vertically down onto the material of substrate workpiece 201 by laser optics 1402. Laser optics 1402 and other beam delivery components may be mounted to a support structure (not shown) to minimize vibration and thermal movements. Focused laser beam 1405 reaches a focal point (voxel 1406) at a point of the glass material of substrate workpiece 201. The translation of the sample through the focus results in laser modification of the material at desired positions and to provide desired effects. In alternative embodiments substrate workpiece 201 remains stationary and focused laser beam 1405 is moved relative to substrate workpiece 201 or both the substrate and laser beam move relative to each other.

Through tailoring of the laser parameters, for example under control of controller 1407, such as power, polarization, pulse length, pulse repetition rate, wavelength and/or speed of translation, structures with desired properties can be created within substrate workpiece 201. The laser parameters that are used depend on the material properties of substrate workpiece 201, and on the desired modifications. In some embodiments, pulse durations from 10 fs to 20 ps, for example 200 fs, pulse repetition rates from 1 kHz to 1 GHz, and pulse energies from 10 nJ to 1 mJ may be used, but any other suitable laser processing parameters may be used in accordance with known laser processing techniques.

By performing laser processing for formation of both the optical elements such as waveguides 102 and alignment holes such as for through glass vias 103 during the same laser processing procedure, for example, without removing substrate workpiece 201 from, or altering its position on, substrate holder 1304, accurate alignment of the optical elements such as waveguides 102 and alignment holes such as for through glass vias 103 can be assured in an efficient manner as discussed herein. For example, the laser processing may include laser ablation as well as or instead of laser modification of material properties followed by etching, or any other suitable laser processing technique. Again, the glass material of substrate workpiece 201 may be maintained in the same position on substrate holder 1304 (e.g., a sample stage or similar structure) while the laser ablation and/or machining is performed to produce both the optical elements such as waveguides 102 and alignment holes such as for through glass vias 103. The discussed laser ablation is not restricted to glass, but may also be used in substrate/packaging materials, such as ABF, solder resist, mold, photoresist, and similar materials.

Following laser processing by irradiating the material with, for example, a focused ultrashort pulsed laser to induce regions of enhanced chemical etch rate, the glass may then be placed in an etch solution (e.g., KOH or HF based) and the regions which have been irradiated etch preferentially with respect to the surrounding material. After etching, surfaces can be processed to improve the surface quality, which can for example consist of a CO2 laser polishing process, a flame polishing process or a chemical smoothing process, as mentioned above.

Returning to FIG. 12, processing continues at operation 1208, where fabrication and assembly operations are completed as known in the art inclusive of forming remaining interconnect features, affixing integrated circuit dies or other devices, singulation, and other package processing, and the resultant structure maybe output. The assembly or package may then be installed in any suitable electronic device such as a laptop, a netbook, a notebook, an ultrabook, a smartphone, a tablet, a personal digital assistant PDA, an ultra-mobile PC, a mobile phone, a desktop computer, a server, a printer, a scanner, a monitor, a set-top box, an entertainment control unit, a digital camera, a portable music player, a digital video recorder, or the like.

FIG. 16 illustrates an example 3D optical waveguide 1600 including glass substrate 101b with angular alignment features 202 such as angular alignment gratings, arranged in accordance with some embodiments. For example, 3D optical waveguide 1600 may be deployed as edge coupling device 116. Although illustrated as coupled to carrier substrate 110, 3D optical waveguide 1600 may be coupled to any suitable substrate or device. As shown, 3D optical waveguide 1600 includes optical waveguides 102b or other 3D laser written features within glass substrate 101b. As discussed herein, optical waveguides 102b or other 3D laser written features within glass substrate 101b are fabricated more accurately based on angular compensation determined using angular alignment features 202. For example, 3D optical waveguide 1600 illustrates an exemplary use of glass-based optical waveguides such as chiplet to package edge routing and coupling.

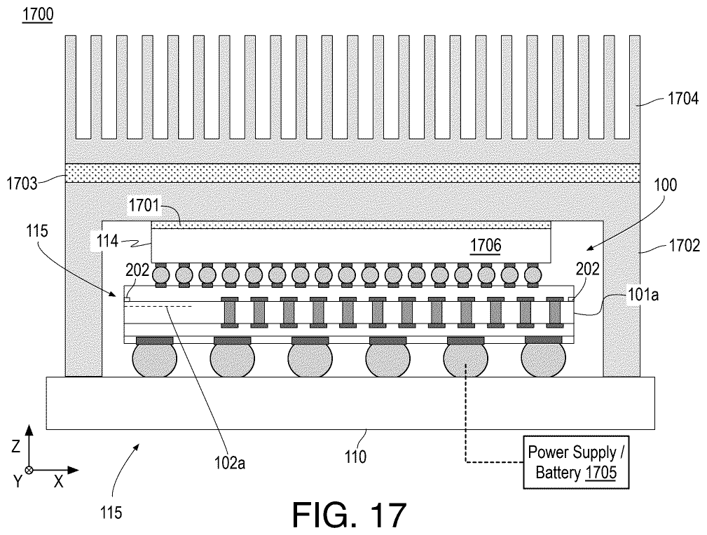

FIG. 17 illustrates an example microelectronic device assembly 1700 including a glass substrate with an angular alignment feature, arranged in accordance with some embodiments. Although illustrated with integrated circuit system 100 including electronic substrate 115 and glass substrate 101b, system or structures inclusive of glass substrate 101a may be embedded in any suitable package structure for deployment in microelectronic device assembly 1700. As shown in FIG. 17, microelectronic device assembly 1700 may include any number of integrated circuit dies including integrated circuit device 114 and/or bridge dies (not shown) mounted to electronic substrate 115 by die level interconnects, redistribution layers, metallization routings, and the like (refer to FIGS. 1A and 1B). Also as shown, glass substrate 101a includes any number of optical waveguides 102a or similar optical features generated using 3D inscription processing. Fabrication of optical waveguides 102a is supported by angular alignment features 202 as discussed herein. Although illustrated with respect to a single integrated circuit die 114, any number of integrated circuit dies, 3D stacked multichip devices, multi-chip composite structures, bridge dies, or the like may be deployed in microelectronic device assembly 1700.

Microelectronic device assembly 1700 further includes a power supply 1705 coupled to one or more of carrier substrate 110, electronic substrate 115, integrated circuit device 114, or other components of microelectronic device assembly 1700. Power supply 1705 may include a battery, voltage converter, power supply circuitry, or the like. Microelectronic device assembly 1700 further includes a thermal interface material (TIM) 1701 disposed on top surfaces of integrated circuit die 1706. TIM 1701 may include any suitable thermal interface material and may be characterized as TIM 1. Integrated heat spreader 1702 having a surface on TIM 1701 extends over integrated circuit die 1706 and electronic substrate 115, and is mounted to carrier substrate 110. Carrier substrate 110 may include any suitable substrate such as a board, motherboard, interposer, or the like. Microelectronic device assembly 1700 further includes TIM 1703 disposed on a top surface of integrated heat spreader 1702. TIM 1703 may include any suitable thermal interface material and may be characterized as TIM 2. TIM 1701 and TIM 1703 may be the same materials, or they may be different. Heat sink 1704 (e.g., an exemplary heat dissipation device or thermal solution) is on TIM 1703 and dissipates heat. Microelectronic device assembly 1700 may be used in desktop and server form factors. In other contexts, a heat solution such as a heat pipe or heat spreader may be mounted directly on TIM 1701. Such assemblies may be used in smaller form factor devices. Other heat dissipation devices may be used.

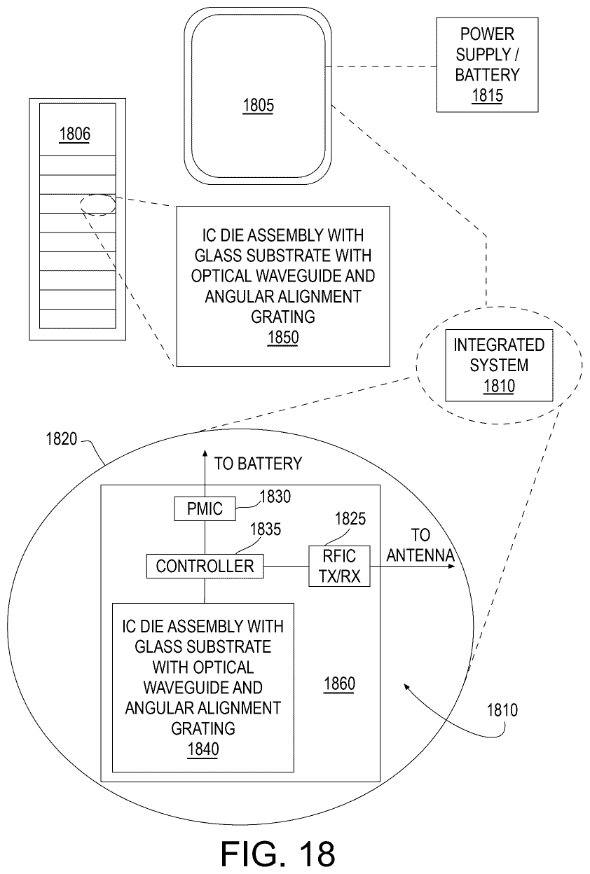

FIG. 18 illustrates exemplary systems deploying a glass substrate with an angular alignment grating, arranged in accordance with some embodiments. The system may be a mobile computing platform 1805 and/or a data server machine 1806, for example. Either may employ a component assembly including a glass substrate with an optical waveguide or similar feature and an angular alignment grating as described herein. Server machine 1806 may be any commercial server, for example, including any number of high-performance computing platforms disposed within a rack and networked together for electronic data processing, which in the exemplary embodiment includes an integrated circuit (IC) die assembly 1850 with a glass substrate with an optical waveguide or similar feature and an angular alignment grating as described elsewhere herein. Mobile computing platform 1805 may be any portable device configured for each of electronic data display, electronic data processing, wireless electronic data transmission, or the like. For example, mobile computing platform 1805 may be any of a tablet, a smart phone, a laptop computer, etc., and may include a display screen (e.g., a capacitive, inductive, resistive, or optical touchscreen), a chip-level or package-level integrated system 1810, and a battery 1815. Although illustrated with respect to mobile computing platform 1805, in other examples, chip-level or package-level integrated system 1810 and battery 1815 may be implemented in a desktop computing platform, an automotive computing platform, an internet of things platform, or the like. As discussed below, in some examples, the disclosed systems may include a sub-system 1860 such as a system on a chip (SOC) or an integrated system of multiple ICs, which is illustrated with respect to mobile computing platform 1805.

Whether disposed within integrated system 1810 illustrated in expanded view 1820 or as a stand-alone packaged device within data server machine 1806, sub-system 1860 may include memory circuitry and/or processor circuitry 1840 (e.g., RAM, a microprocessor, a multi-core microprocessor, graphics processor, etc.), a power management integrated circuit (PMIC) 1830, a controller 1835, and a radio frequency integrated circuit (RFIC) 1825 (e.g., including a wideband RF transmitter and/or receiver (TX/RX)). As shown, one or more IC dies, such as memory circuitry and/or processor circuitry 1840 may be packaged, assembled and implemented, such that the package has one or glass substrates with optical waveguides or similar features and one or more angular alignment gratings as described herein. In some embodiments, RFIC 1825 includes a digital baseband and an analog front end module further comprising a power amplifier on a transmit path and a low noise amplifier on a receive path). Functionally, PMIC 1830 may perform battery power regulation, DC-to-DC conversion, etc., and so has an input coupled to battery 1815, and an output providing a current supply to other functional modules. As further illustrated in FIG. 18, in the exemplary embodiment, RFIC 1825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1840 may provide memory functionality for sub-system 1860, high level control, data processing and the like for sub-system 1860. In alternative implementations, each of the SOC modules may be integrated onto separate ICs coupled to a package substrate, interposer, or board.

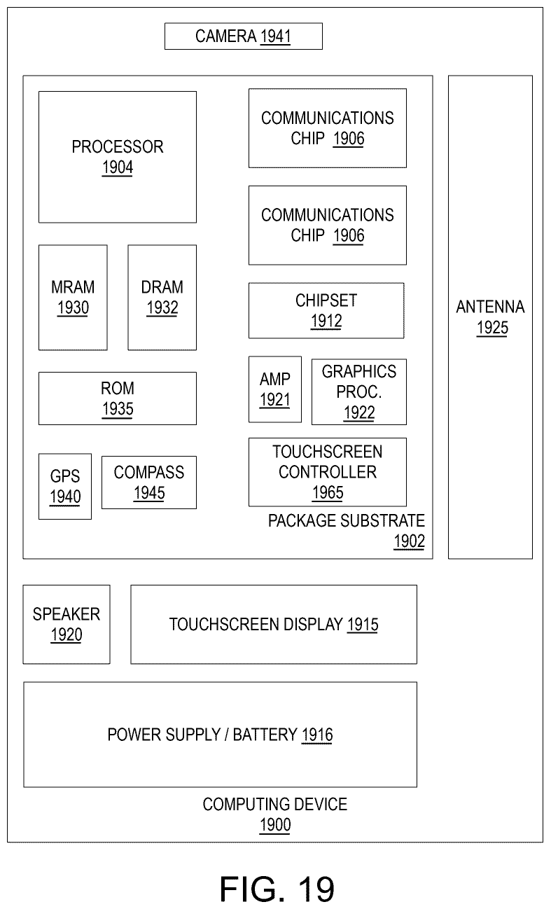

FIG. 19 is a functional block diagram of an electronic computing device 1900, arranged in accordance with some embodiments. For example, device 1900 may, via any suitable component therein, employ a glass substrate with an optical waveguide or similar feature and an angular alignment grating in accordance with any embodiments described elsewhere herein. Device 1900 further includes a motherboard or package substrate 1902 hosting a number of components, such as, but not limited to, a processor 1904 (e.g., an applications processor). Processor 1904 may be physically and/or electrically coupled to package substrate 1902. In some examples, processor 1904 is within a packaged IC assembly that includes a glass substrate with an optical waveguide or similar feature and an angular alignment grating as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1906 may also be physically and/or electrically coupled to the package substrate 1902. In further implementations, communication chips 1906 may be part of processor 1904. Depending on its applications, computing device 1900 may include other components that may or may not be physically and electrically coupled to package substrate 1902. These other components include, but are not limited to, volatile memory (e.g., DRAM 1932), non-volatile memory (e.g., ROM 1935), flash memory (e.g., NAND or NOR), magnetic memory (MRAM 1930), a graphics processor 1922, a digital signal processor, a crypto processor, a chipset 1912, an antenna 1925, touchscreen display 1915, touchscreen controller 1965, battery 1916, audio codec, video codec, power amplifier 1921, global positioning system (GPS) device 1940, compass 1945, an accelerometer, a gyroscope, speaker 1920, camera 1941, and mass storage device (such as hard disk drive, solid-state drive (SSD), compact disk (CD), digital versatile disk (DVD), and so forth, or the like.

Communication chips 1906 may enable wireless communications for the transfer of data to and from the computing device 1900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1906 may implement any of a number of wireless standards or protocols, including, but not limited to, those described elsewhere herein. As discussed, computing device 1900 may include a plurality of communication chips 1906. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertains to exemplary embodiments.

In one or more first embodiments, an apparatus comprises a substrate comprising a layer of glass having a thickness of not less than 50 microns, a first length of not less than 10 mm and a second length orthogonal to the first length of not less than 10 mm, an optical waveguide within the layer of glass, wherein the optical waveguide extends substantially orthogonal to the thickness of the layer of glass, and an angular alignment grating on or within a top surface of the layer of glass, wherein the top surface is substantially orthogonal to the optical waveguide.

In one or more second embodiments, further to the first embodiments, the angular alignment grating is to reflect a selected spectrum of light incident on the angular alignment grating at an angle relative to the top surface of the layer of glass.

In one or more third embodiments, further to the first or second embodiments, the angular alignment grating is to retro-reflect the selected spectrum of light incident on the angular alignment grating at the angle.

In one or more fourth embodiments, further to the first through third embodiments, the angular alignment grating comprises a plurality of structures extending along the top surface of the layer of glass and separated by openings between the structures.

In one or more fifth embodiments, further to the first through fourth embodiments, the plurality of structures each comprise a portion of the layer of glass and wherein the openings extend below the top surface of the layer of glass.

In one or more sixth embodiments, further to the first through fifth embodiments, the plurality of structures each comprise a material other than the layer of glass and wherein the openings extend above the top surface of the layer of glass.

In one or more seventh embodiments, further to the first through sixth embodiments, the plurality of structures each have a serpentine shape along the top surface of the layer of glass.

In one or more eighth embodiments, further to the first through seventh embodiments, the angular alignment grating comprises one of a plurality of angular alignment gratings on or within the top surface, wherein the angular alignment gratings are located at each corner of the layer of glass or along each edge of the layer of glass.

In one or more ninth embodiments, further to the first through eighth embodiments, the apparatus further comprises a microelectronics board, and an integrated circuit die, wherein the substrate is coupled to one of the microelectronics board or the integrated circuit die.

In one or more tenth embodiments, a system comprises a substrate holder to receive a glass substrate, a laser source and a lens system to inscribe the glass substrate, a light source to provide angled incident light on an angular alignment grating on or within a top surface of the glass substrate, a light detector to receive reflected light from the angular alignment grating, and a controller to determine an angle of at least a portion of the top surface of the glass substrate based on the reflected light.

In one or more eleventh embodiments, further to the tenth embodiments, the angled incident light comprises a spectrum of light, and wherein the controller is to determine the angle of the portion of the top surface of the glass substrate based on a detected peak wavelength in the reflected light from the spectrum of light.

In one or more twelfth embodiments, further to the tenth or eleventh embodiments, the angle of the portion of the top surface corresponds to a retro-reflection angle of the angled incident light to the top surface and of the reflected light to the top surface.

In one or more thirteenth embodiments, further to the tenth through twelfth embodiments, the controller is to adjust an inscription voxel location within the glass substrate based on the angle of the portion of the top surface of the glass substrate, the adjustment based on adjustment of one or more of location and/or orientation of the substrate holder, or location and/or orientation of the laser source and/or the lens system.

In one or more fourteenth embodiments, further to the tenth through thirteenth embodiments, the controller is to adjust an inscription voxel location within the glass substrate based on adjustment of a location of a point of focus from the laser source and the lens system.

In one or more fifteenth embodiments, further to the tenth through fourteenth embodiments, wherein the controller is to determine the angle of the portion of the top surface of the glass substrate is based on a wavelength of the reflected light, a diffraction order of the angular alignment grating, and a feature pitch of the angular alignment grating.

In one or more sixteenth embodiments, a method comprises emitting angled incident light on an angular alignment grating on or within a top surface of a glass substrate, receiving reflected light from the angled incident light on the angular alignment grating, determining an angle of at least a portion of the top surface of the glass substrate based on the reflected light, and adjusting a voxel location within the glass substrate based on the angle of the portion of the top surface of the glass substrate.

In one or more seventeenth embodiments, further to the sixteenth embodiments, the angled incident light comprises a spectrum of light, and wherein determining the angle of the portion of the top surface of the glass substrate is based on a detected peak wavelength in the reflected light.

In one or more eighteenth embodiments, further to the sixteenth or seventeenth embodiments, the reflected light is retro-reflected from the angled incident light.

In one or more nineteenth embodiments, further to the sixteenth through eighteenth embodiments, the angular alignment grating comprises a plurality of structures extending along the top surface of the glass substrate and separated by openings between the structures.

In one or more twentieth embodiments, further to the sixteenth through nineteenth embodiments, the angular alignment grating comprises one of a plurality of angular alignment gratings on or within the top surface, wherein the angular alignment gratings are located in a central region of the top surface of the glass substrate and at each corner of the top surface of the glass substrate or along each edge of the top surface of the glass substrate.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a substrate comprising a layer of glass having a thickness of not less than 50 microns, a first length of not less than 10 mm and a second length orthogonal to the first length of not less than 10 mm;
an optical waveguide within the layer of glass, wherein the optical waveguide extends substantially orthogonal to the thickness of the layer of glass; and
an angular alignment grating on or within a top surface of the layer of glass, wherein the top surface is substantially orthogonal to the optical waveguide.

2. The apparatus of claim 1, wherein the angular alignment grating is to reflect a selected spectrum of light incident on the angular alignment grating at an angle relative to the top surface of the layer of glass.

3. The apparatus of claim 2, wherein the angular alignment grating is to retro-reflect the selected spectrum of light incident on the angular alignment grating at the angle.

4. The apparatus of claim 1, wherein the angular alignment grating comprises a plurality of structures extending along the top surface of the layer of glass and separated by openings between the structures.

5. The apparatus of claim 4, wherein the plurality of structures each comprise a portion of the layer of glass and wherein the openings extend below the top surface of the layer of glass.

6. The apparatus of claim 4, wherein the plurality of structures each comprise a material other than the layer of glass and wherein the openings extend above the top surface of the layer of glass.

7. The apparatus of claim 4, wherein the plurality of structures each have a serpentine shape along the top surface of the layer of glass.

8. The apparatus of claim 1, wherein the angular alignment grating comprises one of a plurality of angular alignment gratings on or within the top surface, wherein the angular alignment gratings are located at each corner of the layer of glass or along each edge of the layer of glass.

9. The apparatus of claim 1, further comprising:
a microelectronics board; and
an integrated circuit die, wherein the substrate is coupled to one of the microelectronics board or the integrated circuit die.

10. A system, comprising:
a substrate holder to receive a glass substrate;
a laser source and a lens system to inscribe the glass substrate;
a light source to provide angled incident light on an angular alignment grating on or within a top surface of the glass substrate;
a light detector to receive reflected light from the angular alignment grating; and
a controller to determine an angle of at least a portion of the top surface of the glass substrate based on the reflected light.

11. The system of claim 10, wherein the angled incident light comprises a spectrum of light, and wherein the controller is to determine the angle of the portion of the top surface of the glass substrate based on a detected peak wavelength in the reflected light from the spectrum of light.

12. The system of claim 11, wherein the angle of the portion of the top surface corresponds to a retro-reflection angle of the angled incident light to the top surface and of the reflected light to the top surface.

13. The system of claim 10, wherein the controller is to adjust an inscription voxel location within the glass substrate based on the angle of the portion of the top surface of the glass substrate, the adjustment based on adjustment of one or more of location and/or orientation of the substrate holder, or location and/or orientation of the laser source and/or the lens system.

14. The system of claim 10, wherein the controller is to adjust an inscription voxel location within the glass substrate based on adjustment of a location of a point of focus from the laser source and the lens system.

15. The system of claim 10, wherein the controller is to determine the angle of the portion of the top surface of the glass substrate is based on a wavelength of the reflected light, a diffraction order of the angular alignment grating, and a feature pitch of the angular alignment grating.

16. A method, comprising:
emitting angled incident light on an angular alignment grating on or within a top surface of a glass substrate;
receiving reflected light from the angled incident light on the angular alignment grating;
determining an angle of at least a portion of the top surface of the glass substrate based on the reflected light; and
adjusting a voxel location within the glass substrate based on the angle of the portion of the top surface of the glass substrate.

17. The method of claim 16, wherein the angled incident light comprises a spectrum of light, and wherein determining the angle of the portion of the top surface of the glass substrate is based on a detected peak wavelength in the reflected light.

18. The method of claim 16, wherein the reflected light is retro-reflected from the angled incident light.

19. The method of claim 16, wherein the angular alignment grating comprises a plurality of structures extending along the top surface of the glass substrate and separated by openings between the structures.

20. The method of claim 16, wherein the angular alignment grating comprises one of a plurality of angular alignment gratings on or within the top surface, wherein the angular alignment gratings are located in a central region of the top surface of the glass substrate and at each corner of the top surface of the glass substrate or along each edge of the top surface of the glass substrate.
